(19) United States
(12) Patent Application Publication
(10) Pub. No.: US 2026/0063713 A1
(43) Pub. Date: Mar. 5, 2026

(54) POWER-HARDWARE-IN-THE-LOOP SIMULATION SYSTEM AND METHOD AND NON-TRANSITORY COMPUTER READABLE MEDIUM

(71) Applicant: National Taiwan University of Science and Technology, Taipei City (TW)

(72) Inventors: Kuo-Lung LIAN, Taipei City (TW); Constantine JUAN, New Taipei City (TW)

(21) Appl. No.: 19/046,532

(22) Filed: Feb. 6, 2025

(30) Foreign Application Priority Data
Sep. 3, 2024 (TW) 113133235

(51) Int. Cl. G01R 31/3183

(52) U.S. Cl. CPC G01R 31/318364

(57) ABSTRACT

The present disclosure provides a power-hardware-in-the-loop simulation system, which includes an amplifier, a sensing module, an optimizer and a control module. The amplifier is electrically connected to the device under test, the optimizer is electrically connected to the sensing module, and the control module is electrically connected to the optimizer and the amplifier. The sensing module senses a voltage value of the device under test, and the optimizer obtains a voltage value of the equivalent current source model of a real-time simulator associated with the device under test, and then calculates the reference current value based on a voltage difference between the voltage value of the device under test and the voltage value of the equivalent current source model of the real-time simulator associated with the device under test. The control module controls the amplifier based on the reference current value.

### RELATED APPLICATIONS

This application claims priority to Taiwan Application Serial Number 113133235, filed Sep. 3, 2024, which is herein incorporated by reference.

### BACKGROUND

### Field of the Invention

The present invention relates to a simulation system, and more particularly, a power-hardware-in-the-loop simulation system.

### Description of Related Art

The current power interface of power-hardware-in-the-loop simulation is extremely inconvenient to use. Users need to know the impedance of the device under test. Otherwise, if the ratio of the impedance of the device under test to the equivalent impedance of the power system is violated, the system will be instable. This instability is not a phenomenon that occurs in real systems, but is caused by flaws in the power interface of the current power-hardware-in-the-loop simulation.

It can be seen that the above-mentioned power-hardware-in-the-loop simulation obviously still has inconveniences and defects, and needs to be further improved. In order to solve the above problems, relevant fields have tried their best to find solutions, but no suitable method has been developed for a long time. Therefore, how to overcome the above defects is indeed one of the current important research and development topics, and it has also become an urgent need for improvement in related fields.

### SUMMARY

In one or more various aspects, the present disclosure is directed to a power-hardware-in-the-loop simulation system to overcome the problems of the related art.

An embodiment of the present disclosure is related to a power-hardware-in-the-loop simulation system, which includes an amplifier, a sensing module, an optimizer and a control module. The amplifier is electrically connected to the device under test, the optimizer is electrically connected to the sensing module, and the control module is electrically connected to the optimizer and the amplifier. The sensing module is configured to sense a voltage value of the device under test, and the optimizer is configured to obtain a voltage value of the equivalent current source model of a real-time simulator associated with the device under test and to calculate the reference current value based on a voltage difference between the voltage value of the device under test and the voltage value of the equivalent current source model of the real-time simulator associated with the device under test. The control module is configured to control the amplifier based on the reference current value.

In one embodiment of the present disclosure, whenever the amplifier is controlled by the control module, the optimizer recalculates the reference current value based on the voltage difference between the voltage value of the device under test and the voltage value of the equivalent current source model of the real-time simulator associated with the device under test and re-provides the reference current value to the control module until the optimizer determines that the voltage difference is minimized.

In one embodiment of the present disclosure, the sensing module includes a sensor and an analog to digital converter. The analog to digital converter is electrically connected to the sensor. The sensor is configured to sense an analog voltage of the device under test, and the analog to digital converter is configured to convert the analog voltage into a digital voltage as the voltage value of the device under test.

In one embodiment of the present disclosure, the control module includes a digital to analog converter and a controller. The digital to analog converter is electrically connected to the optimizer, and the controller is electrically connected to the digital to analog converter and the amplifier. The digital to analog converter is configured to convert the reference current value into an analog reference current, and the controller is configured to control a power of the amplifier based on the analog reference current.

In one embodiment of the present disclosure, the device under test is power hardware, and the amplifier, the sensing module, the optimizer and the control module serve as a power interface of a power-hardware-in-the-loop simulation between the device under test and the real-time simulator.

Another embodiment of the present disclosure is related to a power-hardware-in-the-loop simulation method includes steps of: (A) sensing a voltage value of a device under test; (B) obtaining a voltage value of an equivalent current source model of a real-time simulator associated with the device under test, and then calculating a reference current value based on a voltage difference between the voltage value of the device under test and the voltage value of the equivalent current source model of the real-time simulator associated with the device under test through an optimizer; and (C) controlling the amplifier based on the reference current value, wherein the amplifier electrically connected to the device under test.

In one embodiment of the present disclosure, the power-hardware-in-the-loop simulation method further includes: repeating the steps (A) to (C) until the optimizer determines that the voltage difference is minimized.

In one embodiment of the present disclosure, the step (A) includes: sensing an analog voltage of the device under test through a sensor; and converting the analog voltage into a digital voltage as the voltage value of the device under test through an analog to digital converter.

In one embodiment of the present disclosure, the step (C) includes: converting the reference current value into an analog reference current through a digital to analog converter; and controlling a power of the amplifier based on the analog reference current through a controller.

In one embodiment of the present disclosure, the device under test is power hardware.

Technical advantages are generally achieved, by embodiments of the present disclosure. With the power-hardware-in-the-loop simulation system and the power-hardware-in-the-loop simulation method of the present disclosure, the user does not need to know the impedance of the device under test, and as long as there is no instability problem in the actual system, the power-hardware-in-the-loop simulation performed on the device under test by means of the power interface of the present disclosure is stable.

Many of the attendant features will be more readily appreciated, as the same becomes better understood by reference to the following detailed description considered in connection with the accompanying drawings.

### BRIEF DESCRIPTION OF THE DRAWINGS

The invention can be more fully understood by reading the following detailed description of the embodiment, with reference made to the accompanying drawings as follows:

FIG. 1 is a block diagram of a power-hardware-in-the-loop simulation system according to some embodiments of the present disclosure; and

FIG. 2 is a flow chart of a power-hardware-in-the-loop simulation method according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

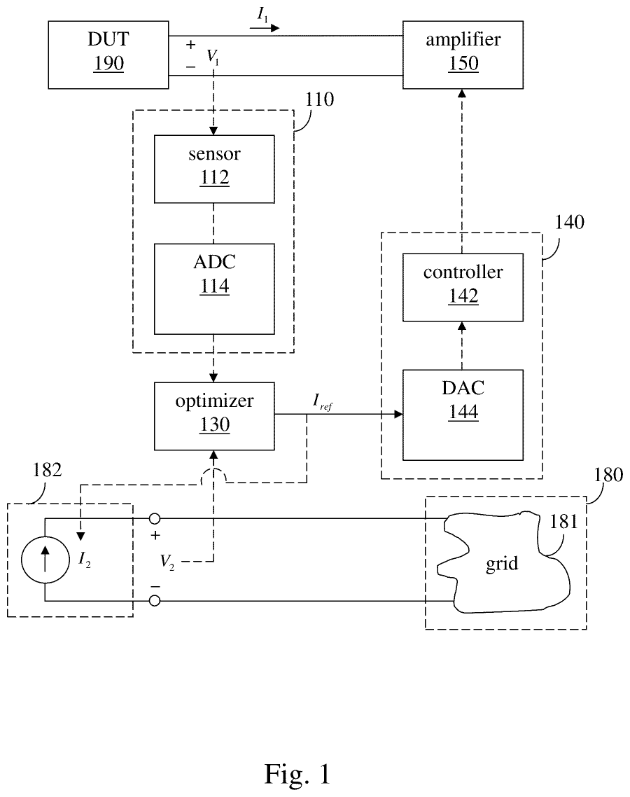

Referring to FIG. 1, in one aspect, the present disclosure is directed to a power-hardware-in-the-loop simulation system. The power-hardware-in-the-loop simulation system can be used to simulate power systems with power-hardware-in-the-loop simulation and may be applicable or readily adaptable to all technologies. Technical advantages are generally achieved by the power-hardware-in-the-loop simulation system according to embodiments of the present disclosure. Herewith the power-hardware-in-the-loop simulation system is described below with FIG. 1.

The subject disclosure provides the power-hardware-in-the-loop simulation system in accordance with the subject technology. Various aspects of the present technology are described with reference to the drawings. In the following description, for purposes of explanation, numerous specific details are set forth in order to provide a thorough understanding of one or more aspects. It can be evident, however, that the present technology can be practiced without these specific details. In other instances, well-known structures and devices are shown in block diagram form to facilitate describing these aspects. The word “exemplary” is used herein to mean “serving as an example, instance, or illustration. ” Any embodiment described herein as “exemplary” is not necessarily to be construed as preferred or advantageous over other embodiments.

It should be understood that the power-hardware-in-the-loop (PHIL) is a real-time simulation form that allows a device under test (DUT) 190 (e.g., a power device under test) and a virtual power system constructed by the real-time simulator 180 to interact simulations. In the power-hardware-in-the-loop simulation, the device under test 190 can be electrically coupled to the real-time simulator 180 through the power interface in the power-hardware-in-the-loop simulation system of the present disclosure. In practice, for example, the real-time simulator 180 can be a digital real-time simulator (RTS), and the grid 181 of the real-time simulator 180 can be simulated as a grid of utility power or mains electricity or another large grid, but the present disclosure is not limited to aforesaid example.

FIG. 1 is a block diagram of a power-hardware-in-the-loop simulation system according to some embodiments of the present disclosure. As shown in FIG. 1, the power-hardware-in-the-loop simulation system includes an amplifier 150, a sensing module 110, an optimizer 130 and a control module 140. In structure, the amplifier 150 is electrically connected to the device under test 190, the optimizer 130 is electrically connected to the sensing module 110, and the control module 140 is electrically connected to the optimizer 130 and the amplifier 150.

It should be noted that when an element is referred to as being “electrically connected” to another element, it can be directly connected or coupled to the other element or intervening elements may be present. For example, the optimizer 130 can be a built-in optimizer that is directly electrically connected to the real-time simulator 180, or the optimizer 130 can be an external optimizer that is indirectly electrically coupled with the real-time simulator 180.

In use, the device under test 190 is modeled as an equivalent current source, which has a current value I₁; the equivalent current source model 182 of the real-time simulator 180, which has a current value I₂. The sensing module 110 senses the voltage value V₁ of the device under test 190. The voltage value V₂ of the equivalent current source model 182 in the real-time simulator 180 is directly sent to the optimizer 130. The optimizer 130 obtains the voltage value V₂ of the equivalent current source model 182 of the real-time simulator 180 associated with (e.g., related to or simulated based on) the device under test 190. For example, during the real-time simulator 180 is simulated to electrically couple with the device under test 190, the optimizer 130 obtains the voltage value V₂ of the equivalent current source model 182 of the real-time simulator 180. Then, the optimizer 130 calculates a reference current value I_{ref} based on a voltage difference between the voltage value V₁ of the device under test 190 and the voltage value V₂ of the equivalent current source model 182 of the real-time simulator 180 associated with the device under test 190. The control module 140 controls the amplifier 150 based on the reference current value I_{ref}, thereby changing the above-mentioned voltage difference.

In practice, for example, the optimizer 130 can be implemented by a part of the hardware in the real-time simulator 180 for executing a software program; or the optimizer 130 can be implemented by an external hardware circuit. The algorithm of the optimizer 130 can use linear search methods, such as a bisectional search, a golden section search, etc.

In some embodiments of the present disclosure, whenever the amplifier 150 is controlled by the control module 140, the optimizer 130 recalculates the reference current value I_{ref} based on the voltage difference between the voltage value V₁ of the device under test 190 and the voltage value V₂ of the equivalent current source model 182 of the real-time simulator 180 associated with the device under test 190 and re-provides the reference current value I_{ref} to the control module 140 until the optimizer 130 determines that the voltage difference is minimized (e.g., a zero voltage difference or an approximately zero voltage difference).

As used herein, “around”, “about”, “substantially” or “approximately” shall generally mean within 20 percent, preferably within 10 percent, and more preferably within 5 percent of a given value or range. Numerical quantities given herein are approximate, meaning that the term “around”, “about”, “substantially” or “approximately” can be inferred if not expressly stated.

In some embodiments of the present disclosure, the device under test 190 is power hardware (e.g., renewable energy equipment, solar equipment, energy storage equipment, etc.), and the amplifier 150, the sensing module 110, the optimizer 130 and the control module 140 serve as a power interface of a power-hardware-in-the-loop simulation between the device under test 190 and the real-time simulator 180. When the reference current value I_{ref} is indeed the real value of the current in the power-hardware-in-the-loop simulation, the voltage values V₁ and V₂ of two ends of the power interface of the power-hardware-in-the-loop simulation is minimized, so as to simulate that the device under test 190 is stably connected to the grid 181 of the real-time simulator 180 without errors.

In some embodiments of the present disclosure, the sensing module 110 includes a sensor 112 and an analog to digital converter (ADC) 114. In structure the analog to digital converter 114 is electrically connected to the sensor 112. In use, the sensor 112 senses an analog voltage of the device under test 190, and the analog to digital converter 114 converts the analog voltage into a digital voltage as the voltage value V₁ of the device under test 190.

In some embodiments of the present disclosure, the control module 140 includes a digital to analog converter (DAC) 144 and a controller 142. In structure, the controller 142 is electrically connected to the digital to analog converter 144 and the amplifier 150, and the digital to analog converter 144 is electrically connected to the optimizer 130. In use, the digital to analog converter 144 converts the reference current value I_{ref} into an analog reference current, and the controller 142 controls the power of the amplifier 150 based on the analog reference current. For example, the amplifier 150 can be a power amplifier, such as a switched-mode power amplifier, but the present disclosure is not limited to this example.

In a control experiment, if the equivalent current source model 182 is replaced by an equivalent voltage source model and the optimizer 130 is omitted, there will be impedance constraints due to voltage and current conversion across different fields, causing the system's stable region to be narrow. In this way, every time a parameter is changed or the device under test 190 is changed, it is difficult for the user to determine whether it is a problem in the power-hardware-in-the-loop simulation of the above-mentioned control experiment or other problems.

In practice, the stable region of the power-hardware-in-the-loop simulation system in FIG. 1 is much larger than the stable region of the system of the above-mentioned control experiment. The user does not need to know the impedance of the device under test 190, and as long as there is no stability problem with the power-hardware-in-the-loop simulation system in FIG. 1, the power-hardware-in-the-loop simulation performed on the device under test 190 by means of the power interface of the present disclosure has no instability problems.

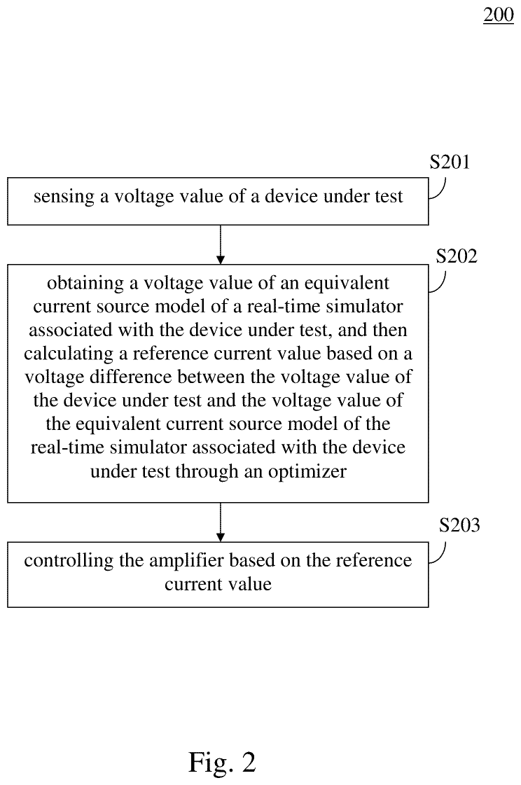

In order to further elaborate on the method of running the power-hardware-in-the-loop simulation system in FIG. 1, refer to FIGS. 1 to 2 at the same time. FIG. 2 is a flow chart of a power-hardware-in-the-loop simulation method 200 according to some embodiments of the present disclosure. As shown in FIG. 2, the power-hardware-in-the-loop simulation method 200 includes steps S201-S203. However, as could be appreciated by persons having ordinary skill in the art, for the steps described in the present embodiment, the sequence in which these steps are performed, unless explicitly stated otherwise, can be altered depending on actual needs; in certain cases, all or some of these steps can be performed concurrently.

The power-hardware-in-the-loop simulation method 200 may take the form of a computer program product on a computer-readable storage medium having computer-readable instructions embodied in the medium. Any suitable storage medium may be used including non-volatile memory such as read only memory (ROM), programmable read only memory (PROM), erasable programmable read only memory (EPROM), and electrically erasable programmable read only memory (EEPROM) devices; volatile memory such as SRAM, DRAM, and DDR-RAM; optical storage devices such as CD-ROMs and DVD-ROMs; and magnetic storage devices such as hard disk drives and floppy disk drives.

Referring to FIGS. 1 to 2 at the same time, in step S201, the voltage value V₁ of the device under test 190 is sensed; in step S202, the voltage value V₂ of the equivalent current source model 182 of the real-time simulator 180 associated with the device under test 190 is obtained, and then the reference current value I_{ref} based on a voltage difference between the voltage value V₁ of the device under test 190 and the voltage value V₂ of the equivalent current source model 182 of the real-time simulator 180 associated with the device under test 190 is calculated through the optimizer 130; in step S203, the amplifier 150 is controlled based on reference current value I_{ref}.

In one embodiment of the present disclosure, the power-hardware-in-the-loop simulation method 200 further includes: repeating steps S201-S203 until the optimizer 130 determines that the voltage difference is minimized.

In one embodiment of the present disclosure, step S201 includes: sensing an analog voltage of the device under test 190 through the sensor 112; and converting the analog voltage into a digital voltage as the voltage value V₁ of the device under test 190 through the analog to digital converter 114.

In one embodiment of the present disclosure, step S202 includes: converting the reference current value I_{ref} into an analog reference current through the digital to analog converter 144; and controlling the power of the amplifier 150 based on the analog reference current through the controller 142.

In view of above, technical advantages are generally achieved, by embodiments of the present disclosure. With the power-hardware-in-the-loop simulation system and the power-hardware-in-the-loop simulation method 200 of the present disclosure, the user does not need to know the impedance of the device under test 190, and as long as there is no instability problem in an actual system, the power-hardware-in-the-loop simulation performed on the device under test 190 by means of the power interface of the present disclosure is stable.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A power-hardware-in-the-loop simulation system, comprising:
an amplifier electrically connected to a device under test;
a sensing module configured to sense a voltage value of the device under test;
an optimizer electrically connected to the sensing module, and the optimizer configured to obtain a voltage value of an equivalent current source model of a real-time simulator associated with the device under test and to calculate a reference current value based on a voltage difference between the voltage value of the device under test and the voltage value of the equivalent current source model of the real-time simulator associated with the device under test; and
a control module electrically connected to the optimizer and the amplifier, and control module configured to control the amplifier based on the reference current value.

2. The power-hardware-in-the-loop simulation system of claim 1, wherein whenever the amplifier is controlled by the control module, the optimizer recalculates the reference current value based on the voltage difference between the voltage value of the device under test and the voltage value of the equivalent current source model of the real-time simulator associated with the device under test and re-provides the reference current value to the control module until the optimizer determines that the voltage difference is minimized.

3. The power-hardware-in-the-loop simulation system of claim 1, wherein the sensing module comprises:
a sensor configured to sense an analog voltage of the device under test; and
an analog to digital converter electrically connected to the sensor, and the analog to digital converter configured to convert the analog voltage into a digital voltage as the voltage value of the device under test.

4. The power-hardware-in-the-loop simulation system of claim 1, wherein the control module comprises:
a digital to analog converter electrically connected to the optimizer, and the digital to analog converter configured to convert the reference current value into an analog reference current; and
a controller electrically connected to the digital to analog converter and the amplifier, and the controller configured to control a power of the amplifier based on the analog reference current.

5. The power-hardware-in-the-loop simulation system of claim 1, wherein the device under test is power hardware, and the amplifier, the sensing module, the optimizer and the control module serve as a power interface of a power-hardware-in-the-loop simulation between the device under test and the real-time simulator.

6. A power-hardware-in-the-loop simulation method, comprising steps of:
(A) sensing a voltage value of a device under test;
(B) obtaining a voltage value of an equivalent current source model of a real-time simulator associated with the device under test, and then calculating a reference current value based on a voltage difference between the voltage value of the device under test and the voltage value of the equivalent current source model of the real-time simulator associated with the device under test through an optimizer; and
(C) controlling an amplifier based on the reference current value, wherein the amplifier electrically connected to the device under test.

7. The power-hardware-in-the-loop simulation method of claim 6, further comprising:
repeating the steps (A) to (C) until the optimizer determines that the voltage difference is minimized.

8. The power-hardware-in-the-loop simulation method of claim 6, wherein the step (A) comprises:
sensing an analog voltage of the device under test through a sensor; and
converting the analog voltage into a digital voltage as the voltage value of the device under test through an analog to digital converter.

9. The power-hardware-in-the-loop simulation method of claim 6, wherein the step (C) comprises:
converting the reference current value into an analog reference current through a digital to analog converter; and
controlling a power of the amplifier based on the analog reference current through a controller.

10. The power-hardware-in-the-loop simulation method of claim 6, wherein the device under test is power hardware.

11. A non-transitory computer readable medium to store a plurality of instructions for commanding a computer to execute a power-hardware-in-the-loop simulation method, and the power-hardware-in-the-loop simulation method comprising steps of:
(A) sensing a voltage value of a device under test;
(B) obtaining a voltage value of an equivalent current source model of a real-time simulator associated with the device under test, and then calculating a reference current value based on a voltage difference between the voltage value of the device under test and the voltage value of the equivalent current source model of the real-time simulator associated with the device under test through an optimizer; and
(C) controlling an amplifier based on the reference current value, wherein the amplifier electrically connected to the device under test.

12. The non-transitory computer readable medium of claim 11, wherein the power-hardware-in-the-loop simulation method further comprises:
repeating the steps (A) to (C) until the optimizer determines that the voltage difference is minimized.

13. The non-transitory computer readable medium of claim 11, wherein the step (A) comprises:
sensing an analog voltage of the device under test through a sensor; and
converting the analog voltage into a digital voltage as the voltage value of the device under test through an analog to digital converter.

14. The non-transitory computer readable medium of claim 11, wherein the step (C) comprises:
converting the reference current value into an analog reference current through a digital to analog converter; and
controlling a power of the amplifier based on the analog reference current through a controller.

15. The non-transitory computer readable medium of claim 11, wherein the device under test is power hardware.
